(19) United States
(12) Patent Application Publication
(10) Pub. No.: US 2019/0103282 A1
(43) Pub. Date: Apr. 4, 2019

(54) Etching Solution for Simultaneously Removing Silicon and Silicon-Germanium Alloy From a Silicon-Germanium/Silicon Stack During Manufacture of a Semiconductor Device

(71) Applicant: Versum Materials US, LLC, Tempe, AZ (US)

(72) Inventors: Jhih Kuei Ge, Chupei City (TW); Yi-Chia Lee, Danshu (TW); Wen Dar Liu, Chupei City (TW); Chi-Hsien Kuo, Chupei City (TW); Andrew J. Adamczyk, Auburn, AL (US)

(73) Assignee: Versum Materials US, LLC, Tempe, AZ (US)

(21) Appl. No.: 16/142,291

(22) Filed: Sep. 26, 2018

Related U.S. Application Data
(60) Provisional application No. 62/565,704, filed on Sep. 29, 2017.

(51) Int. Cl. H01L 21/306; H01L 21/3105; H01L 21/02; H01L 29/06; H01L 29/423; H01L 29/10

(52) U.S. Cl. CPC H01L 21/30608; H01L 21/3105; H01L 21/02532; H01L 29/1079; H01L 29/0673; H01L 29/42392; H01L 21/02603

(57) ABSTRACT

Described herein is an etching solution suitable for the simultaneous removal of silicon and silicon-germanium from a microelectronic device, which comprises: water; an oxidizer; a buffer composition comprising an amine compound (or ammonium compound) and a polyfunctional organic acid; a water-miscible solvent; and a fluoride ion source.

### CROSS-REFERENCE TO RELATED APPLICATIONS

This application claims priority under 35 U.S.C. § 119(e) to U.S. provisional patent application No. 62/565,704, filed on Sep. 29, 2017, the entirety of which is incorporated herein by reference.

### BACKGROUND OF THE INVENTION

The present invention relates to aqueous etching solutions used in the manufacture of semiconductor devices, methods of using them and systems thereof. More specifically, the invention provides an aqueous etching solution that simultaneously etches silicon and silicon-germanium alloy in silicon-germanium/silicon composite semiconductor devices.

With constant down-scaling and increasingly demanding requirements to the speed and functionality of ultra-high density integrated circuits, conventional planar metal-oxide-semiconductor field effect transistors (MOSFETs) face increasing challenges with such issues as scaling of gate oxide thickness and electrostatic control of the gate electrode over the channel region. Fin field effect transistors (FinFETs) have exhibited improved control over a planar gate MOSFET design by wrapping the gate electrode over three sides of a fin-shaped channel.

GAA MOSFETs are similar to FinFETs but have the potential of even greater electrostatic control over the channel because the gate electrode completely surrounds the channel. In a GAA MOSFET, the channel region is essentially a nanowire. The nanowire channel typically has a thickness (or diameter) in the tens of nanometers (nm) or less and has an unconstrained length. The nanowire channel is suspended generally horizontally between, and anchored to, the much larger source and drain regions of the GAA MOSFET.

GAA MOSFETs can be fabricated on a bulk silicon substrate utilizing fully compatible CMOS technology. A typical manufacturing method of forming the channel regions in a GAA MOSFET involves epitaxially growing a stack (epi-stack) of sacrificial layers sandwiched between channel layers on top of a bulk substrate. The sacrificial layers and channel layers are composed of two different materials so that selective etching can remove the sacrificial layers.

By way of example, an epi-stack can be formed of alternating silicon (Si) and silicon germanium (SiGe) layers, wherein the Si layers are the sacrificial layers and the SiGe layers are the channel layers. The Si layers can then be removed by selective etching (for example via a wet etching process such as a TMAH), which also inadvertently recesses trenches into the bulk substrate due to the similarity of materials composing the sacrificial layers and the substrate. The SiGe layers can subsequently be formed into the nanowire channels suspended over the trenches. A thin gate dielectric is then disposed around the SiGe nanowire channels and over the recessed trenches of the substrate. Metal is then disposed over the dielectric to form the metal gate electrode of the GAA MOSFET.

There are also situations when both silicon and silicon-germanium need to be etched simultaneously such as, for example, in fin trimming. The application of simultaneous Si/SiGe fin trimming is typically employed for 5 nm technology. There are two types of fin on pattern, including Si and SiGe. Because the fins would go through some process steps, if the original fin width is too narrow, it may cause fin collapse issue. Therefore, wider fins may be initially produced and then they are trimmed by a wet etch process to avoid fin collapsing. There is a need in the art for an etching chemistry that targets Si and SiGe to reduce the fin thickness to be equal to about 1 nm, and the chemistry must be compatible with oxides & nitrides.

### BRIEF SUMMARY OF THE INVENTION

In one aspect, the present invention provides an etching solution suitable for the simultaneous removal of silicon and silicon-germanium from a microelectronic device, which comprises water; an oxidizer; a buffer composition comprising an amine compound and a polyfunctional organic acid; a water-miscible solvent; and a fluoride ion source.

In another aspect, the present invention provides a method for simultaneously etching silicon and silicon-germanium from a microelectronic device (composite semiconductor device) comprising silicon and silicon-germanium, the method comprising the steps of: contacting the microelectronic device (composite semiconductor device) comprising silicon and silicon-germanium with an aqueous composition (which may be referred to as an etching solution or etching composition herein) comprising water; an oxidizer; a buffer composition comprising an amine compound and a polyfunctional organic acid; a water-miscible solvent; and a fluoride ion source; and rinsing the microelectronic device (composite semiconductor device) after the silicon and silicon-germanium is at least partially removed, wherein the etch rate for silicon relative to silicon-germanium is about 1.0. The method conditions, such as time and temperature, may be increased or decreased to modify the removal rates. The contacting step may use any of the compositions of this invention.

The embodiments of the invention can be used alone or in combinations with each other.

### DETAILED DESCRIPTION OF THE INVENTION

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention. The use of the term “comprising” in the specification and the claims includes the more narrow language of “consisting essentially of” and “consisting of.”

Embodiments of this invention are described herein, including the best mode known to the inventors for carrying out the invention. Variations of those embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

The present invention relates generally to compositions useful for the selective removal of silicon and silicon-germanium from a microelectronic device having such material(s) thereon during its manufacture.

It will be understood that the term “silicon” as deposited as a material on a microelectronic device will include polysilicon.

For ease of reference, “microelectronic device” or “semiconductor device” corresponds to semiconductor substrates, for examples wafers, flat panel displays, phase change memory devices, solar panels and other products including solar substrates, photovoltaics, and microelectromechanical systems (MEMS), manufactured for use in microelectronic, integrated circuit, or computer chip applications. Solar substrates include, but are not limited to, silicon, amorphous silicon, polycrystalline silicon, monocrystalline silicon, CdTe, copper indium selenide, copper indium sulfide, and gallium arsenide on gallium. The solar substrates may be doped or undoped. It is to be understood that the term “microelectronic device” is not meant to be limiting in any way and includes any substrate that will eventually become a microelectronic device or microelectronic assembly.

A “composite semiconductor device” or “composite microelectronic device” means that the device has more than one materials and/or layers and/or portions of layers present on a non-conductive substrate. The materials may comprise high K dielectrics, and/or low K dielectrics and/or barrier materials and/or capping materials and/or metal layers and/or others known to persons of skill.

As defined herein, “low-k dielectric material” corresponds to any material used as a dielectric material in a layered microelectronic device, wherein the material has a dielectric constant less than about 3.5. Preferably, the low-k dielectric materials include low-polarity materials such as silicon-containing organic polymers, silicon-containing hybrid organic/inorganic materials, organosilicate glass (OSG), TEOS, fluorinated silicate glass (FSG), silicon dioxide, and carbon-doped oxide (CDO) glass. It is to be appreciated that the low-k dielectric materials may have varying densities and varying porosities.

As defined herein, “high-K dielectric material” refers to a material with a high dielectric constant K (as compared to silicon dioxide). High-K dielectrics may be used to replace a silicon dioxide gate dielectric or another dielectric layer of a microelectronic device. The high-k material may be hafnium dioxide (HfO₂), hafnium oxynitride (HfON), zirconium dioxide (ZrO₂), zirconium oxynitride (ZrON), aluminum oxide (Al₂O₃), aluminum oxynitride (AlON), hafnium silicon oxide (HfSiO₂), hafnium aluminum oxide (HfAlO), zirconium silicon oxide (ZrSiO₂), tantalum dioxide (Ta₂O₅), aluminum oxide, Y₂O₃, La₂O₃, titanium oxide (TiO₂), aluminum doped hafnium dioxide, bismuth strontium titanium (BST), or platinum zirconium titanium (PZT).

As defined herein, the term “barrier material” corresponds to any material used in the art to seal the metal lines, e.g., copper interconnects, to minimize the diffusion of said metal, e.g., copper, into the dielectric material. Preferred barrier layer materials include tantalum, titanium, ruthenium, hafnium, and other refractory metals and their nitrides and silicides.

“Substantially free” is defined herein as less than 0.001 wt. %. “Substantially free” also includes 0.000 wt. %. The term “free of” means 0.000 wt. %.

As used herein, “about” is intended to correspond to ±5% of the stated value.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.001 weight percent, based on the total weight of the composition in which such components are employed. Unless otherwise defined, all the amounts reported herein are in weight percent of the total composition, that is 100%.

In the broad practice of this invention, the etching solution of the invention comprises, consists essentially of, or consists of water; an oxidizer; a buffer composition comprising an amine compound and a polyfunctional organic acid; a water-miscible solvent; and a fluoride ion source.

In some embodiments, the etching solution compositions disclosed herein are formulated to be substantially free or free of at least one of the following chemical compounds: ammonium hydroxide, quaternary ammonium hydroxides (e.g., TMAH, TEAH, ETMAH), and inorganic bases.

The compositions of the present invention are suitable for use in a process for making a gate all around structure on an electronic device. Such processes are known in the art such as, for example, the process disclosed in U.S. patent application Publication No. 2017/0179248, U.S. patent application Publication No. 2017/0104062, U.S. patent application Publication No. 2017/0133462, and U.S. patent application Publication No. 2017/0040321, the disclosures of which are fully incorporated herein by reference.

The headings employed herein are not intended to be limiting; rather, they are included for organizational purposes only.

The compositions disclosed herein exhibit excellent simultaneous removal of silicon and silicon-germanium.

Water

The etching compositions of the present invention are aqueous-based and, thus, comprise water. In the present invention, water functions in various ways such as, for example, to dissolve one or more components of the composition, as a carrier of the components, as an aid in the removal of residue, as a viscosity modifier of the composition, and as a diluent. Preferably, the water employed in the cleaning composition is de-ionized (DI) water. The ranges of water described in the next paragraph include all of the water in the composition from any source.

It is believed that, for most applications, the weight percent of water in the composition will be present in a range with start and end points selected from the following group of numbers: 0.5, 1, 5, 10, 15, 20, 25, 30, 40, 50 60, 65, 68 70, 71, 72, 73, 74, 75, 76, 77, 78, 79, 80, 82, 85, 87, 90, 92, 95 and 96. Examples of the ranges of water that may be used in the composition include, for examples, from about 0.5% to about 90% by wt., or 10% to about 80% by wt. of water; or from about 15% to about 80% by wt., or from about 20% to about 80% by wt., or from about 40% to about 75% by wt., or from about 50% to about 85% by wt.; or from about 65% to about 90% by wt.; or from 70 to about 80% by wt. or from 65 to about 85% by wt. of water. Still other preferred embodiments of the present invention may include water in an amount to achieve the desired weight percent of the other ingredients. (Note the water ranges defined herein include the total water in the composition. The ranges, therefore, include water that is added as part of other components that may be for example, added as an aqueous solution to the composition.)

### Oxidizer

The etching compositions of the present invention comprise an oxidizing agent, also referred to as an “oxidizer.” The oxidizer functions primarily to etch the silicon and the silicon-germanium alloy by forming a corresponding oxide (i.e., germanium or silicon). The oxidizing agent can be any suitable oxidizing agent. Suitable oxidizing agents include, but are not limited to, one or more peroxy-compounds, i.e., compounds that comprise at least one peroxy group (—O—O—). Suitable peroxy-compounds include, for example, peroxides, persulfates (e.g., monopersulfates and dipersulfates), percarbonates, and acids thereof, and salts thereof, and mixtures thereof. Other suitable oxidizing agents include, for example, oxidized halides (e.g., iodates, periodates, and acids thereof, and mixtures thereof, and the like), perboric acid, perborates, percarbonates, peroxyacids (e.g., peracetic acid, perbenzoic acid, salts thereof, mixtures thereof, and the like), permanganates, cerium compounds, ferricyanides (e.g., potassium ferricyanide), mixtures thereof, and the like.

In some embodiments, oxidizing agents include, but are not limited to, hydrogen peroxide, periodic acid, potassium iodate, potassium permanganate, ammonium persulfate, ammonium molybdate, ferric nitrate, nitric acid, potassium nitrate, ammonia, and mixtures thereof. In still other embodiments, oxidizing agents include hydrogen peroxide and urea-hydrogen peroxide. In some embodiments, the oxidizing agent is hydrogen peroxide.

In some embodiments, the amount of oxidizer (neat) will comprise from about 0.1% to about 20% by weight, or from about 1.0% to about 20% by weight, or from about 1.5% to about 15% by weight, or from 1.5% to about 10% by weight, or from 2% to about 10% by weight of the composition or any other wt % range based on the total weight of the composition having start and end points selected from: 0.1, 0.3, 0.5, 1, 1.5, 2, 2.5, 3, 3.5, 4, 4.5, 5, 5.5, 6, 7, 8, 9, 10, 15 and 20.

### Fluoride Ion Source

The etching compositions of the present disclosure also comprise one or more sources of fluoride ion. Fluoride ion functions principally to assist in removal of silicon and germanium oxide that has formed upon action of the oxidizer. Typical compounds that provide a fluoride ion source according to the present invention are hydrofluoric acid, ammonium fluoride, quaternary ammonium fluorides such as, for example, fluoroborates, fluoroboric acid, tetrabutylammonium tetrafluoroborate, aluminum hexafluoride, and a fluoride salt of an aliphatic primary, secondary or tertiary amine having the formula:

R¹NR²R³R⁴F,

wherein R¹, R², R³ and R⁴ individually represent H or a (C₁-C₄) alkyl group. Typically, the total number of carbon atoms in the R¹, R², R³ and R⁴ groups is 12 carbon atoms or less. Examples of fluoride salts of an aliphatic primary, secondary or tertiary amine such as, for example, tetramethylammonium fluoride, tetraethylammonium fluoride, methyltriethylammonium fluoride, and tetrabutylammonium fluoride.

In selecting the source of the fluoride ion, consideration should be given as to whether or not the source releases ions that would adversely affect the surface being cleaned. For example, in cleaning semiconductor elements, the presence of sodium or calcium ions in the cleaning composition can have an adverse effect on the surface of the element. In some embodiments, the fluoride ion source is ammonium fluoride.

It is believed that the amount of the compound used as the source of the fluoride ion in the cleaning composition will, for most applications, comprise, from about 0.01 to about 10% by weight, or from about 0.01 to about 8% by weight of a solution 40% ammonium fluoride, or stoichiometric equivalent thereof. Preferably, the compound comprises from about 0.02 to about 8% by weight, more preferably from about 0.02 to about 6% by weight, still more preferably, about 1 to about 8% by weight, and most preferably, from about 0.025% to about 5% by weight of a solution of about 40% ammonium fluoride. (Typically the ammonium fluoride solution is an aqueous solution.) In some embodiments, the composition will comprise from about 0.01 to about 8% by weight or about 0.01 to about 7% by weight of a fluoride ion source, which may be provided by a 40% ammonium fluoride solution. Preferably, the compound comprises from about 0.02 to about 6% by weight of a fluoride ion source and, most preferably, from about 0.025% to about 5% or from about 0.04 to about 2.5% by weight of a fluoride ion source or from about 0.05 to about 15% by weight of a solution of 40% ammonium fluoride, most preferably, from about 0.0625% to about 12.5%, or from about 0.1 to about 6.25% by weight of a solution of 40% ammonium fluoride. The % by weight of a solution of 40% ammonium fluoride that may be added to the composition include any range having start and endpoints selected from the following group of numbers: 0.01, 0.02, 0.025, 0.04, 0.05, 0.06, 0.5, 0.6, 0.75, 0.1, 0.2, 0.5, 0.6, 0.75. 1, 2, 2.5, 3, 3.5, 4, 5, 6, 7, 8, 10, 12.5, 15, 17, 18, and 20. The % by weight of fluoride ion source (neat) that may be added to the composition includes any range having start and endpoints selected from the following group of numbers: 0.01, 0.02, 0.025, 0.04, 0.05, 0.06, 0.5, 0.6, 0.75, 0.1, 0.2, 0.5, 0.6, 0.75, 1, 1.2, 1.4, 1.6, 1.8, 2, 2.2, 2.5, 2.7, 3, 3.5, 4, 4.5, 5, 5.5, 6, 7, 8, 10, 12.5, 15, 17, 18, 20, 25, 30, 35, 40, 45 and 50. The % by weight of fluoride ion source (neat) that may be added to the composition includes, for examples, from about 0.025% to about 5%, or from about 0.04 to about 2.5%, or from about 0.1% to about 2%, or from about 0.5 to about 1.5% by weight of a fluoride ion source.

It should be understood that the amount of fluoride ion used will typically depend, however, on the particular substrate being cleaned. For example, in certain cleaning applications, the amount of the fluoride ion can be relatively high when cleaning substrates that comprise dielectric materials that have a high resistance to fluoride etching. Conversely, in other applications, the amount of fluoride ion should be relatively low, for example, when cleaning substrates that comprise dielectric materials that have a low resistance to fluoride etching.

### Water-Miscible Solvent

The etching compositions of the present invention comprise a water-miscible solvent. The water-miscible solvent may function to inhibit the silicon etch rate and to boost the silicon-germanium etch rate. Examples of water-miscible organic solvents that can be employed are ethylene glycol, propylene glycol (PG), butyl diglycol (BDG), 1,4-butanediol, tripropylene glycol methyl ether, propylene glycol propyl ether, diethylene gycol n-butyl ether (e.g., commercially available under the trade designation Dowanol DB), hexyloxypropylamine, poly(oxyethylene)diamine, dimethylsulfoxide (DMSO), tetrahydrofurfuryl alcohol, glycerol, alcohols, sulfoxides, or mixtures thereof. Preferred solvents are alcohols, diols, or mixtures thereof. Most preferred solvents are diols such as, for example, butyl diglycol.

In some embodiments of the present invention, the water-miscible organic solvent may comprise a glycol ether. Examples of glycol ethers include ethylene glycol monomethyl ether, ethylene glycol monoethyl ether, ethylene glycol monobutyl ether, ethylene glycol dimethyl ether, ethylene glycol diethyl ether, diethylene glycol monomethyl ether, diethylene glycol monoethyl ether, diethylene glycol monopropyl ether, diethylene glycol monoisopropyl ether, diethylene glycol monobutyl ether, diethylene glycol monoisobutyl either, diethylene glycol monobenzyl ether, diethylene glycol dimethyl ether, diethylene glycol diethyl ether, triethylene glycol monomethyl ether, triethylene glycol dimethyl ether, polyethylene glycol monomethyl ether, diethylene glycol methyl ethyl ether, triethylene glycol methyl ethyl ether, ethylene glycol monomethyl ether acetate, ethylene glycol monethyl ether acetate, propylene glycol methyl ether acetate, propylene glycol monomethyl ether, propylene glycol dimethyl ether, propylene glycol monobutyl ether, propylene glycol, monopropyl ether, dipropylene glycol monomethyl ether (DPM), dipropylene glycol monopropyl ether, dipropylene glycol monoisopropyl ether, dipropylene monobutyl ether, diproplylene glycol diisopropyl ether, tripropylene glycol monomethyl ether, 1-methoxy-2-butanol, 2-methoxy-1-butanol, 2-methoxy-2-methylbutanol, 1,1-dimethoxyethane and 2-(2-butoxyethoxy) ethanol.

It is believed that, for most applications, the amount of water-miscible organic solvent in the composition may be in a range having start and end points selected from the following list of weight percents: 0.5, 1, 5, 7, 9, 12, 15, 20, 25, 28, 30, 35, 40, 45, 50, 59.5, 62, 65. Examples of such ranges of solvent include from about 0.5% to about 59.5% by weight; or from about 1% to about 50% by weight; or from about 0.5% to about 50%, or from about 1% to about 40% by weight; or from about 0.5% to about 30% by weight; or from about 1% to about 30% by weight; or from about 5% to about 30% by weight; or from about 5% to about 15% by weight; or from about 7% to about 12%, or from about 10% to about 25%, or from about 15% to about 25% by weight of the composition.

### Amine Compound

Compositions of the present invention comprise an amine compound which may function in one or more of the following roles: as a pH adjustor, a complexing agent and/or as the conjugate base in a buffer composition, preferably predominantly as a pH adjustor. Suitable amine compounds include at least one alkanolamine. Preferred alkanolamines include the lower alkanolamines which are primary, secondary and tertiary having from 1 to 5 carbon atoms. Examples of such alkanolamines include N-methylethanolamine (NMEA), monoethanolamine (MEA), diethanolamine, mono-, di- and triisopropanolamine, 2-(2-aminoethylamino)ethanol, 2-(2-aminoethoxy)ethanol, triethanolamine, N-ethyl ethanolamine, N,N-dimethylethanolamine, N,N-diethyl ethanolamine, N-methyl diethanolamine, N-ethyl diethanolamine, cyclohexylaminediethanol, and mixtures thereof.

In preferred embodiments, the amine compound is an alkanolamine selected from the group consisting of triethanolamine (TEA), diethanolamine, N-methyl diethanolamine, diisopropanolamine, monoethanol amine, amino(ethoxy) ethanol (AEE), N-methyl ethanol amine, monoisopropanol amine, cyclohexylaminediethanol, and mixtures thereof.

It is believed that the amount of the amine compound in the composition will, for the most applications, comprise from about 0.01% to about 50% by weight of the composition, specifically, about 0.08% to about 40% by weight of the composition, or more specifically, about 0.2% to about 30% by weight of the composition. In some embodiments, the amine compound comprises from about 0.02% to about 15% weight percent and, more specifically, from about 0.03 to about 12% or about from 0.3 to about from 7% by weight or about from 0.1 to about from 3% by weight of the composition. The weight percent of amine in the composition may be present in a range with start and end points selected from the following group of numbers: 0.01, 0.02, 0.03, 0.04, 0.05, 0.7, 0.09. 0.1, 0.2, 0.3, 0.5, 0.7, 0.9, 1, 1.2, 1.5, 1.7, 2, 2.5, 3, 3.5, 5, 7, 10, 12, 15, 20, 25, 30, 35, 40, 45 and 50.

The amine compound, if employed in excess may also serve as the base component of a buffer if a corresponding conjugate acid is employed such as, for example, a polyfunctional organic acid.

### Buffer

The etching compositions include a buffer composition. Typically, the buffer composition comprises, consists essentially of, or consists of an amine compound (as detailed above) and/or other bases and/or ammonium salts and the polyfunctional organic acid as detailed below. In addition to the amine compound, additional or alternate bases and/or ammonium salts may be added to the composition to work with the polyfunctional organic acid to buffer the composition.

In some embodiments, the buffer employed comprises ammonium salts paired with one or more polyfunctional organic acids, which function primarily as the conjugate acid portion of the buffer. As used herein, the term “polyfunctional organic acid” refers to an acid or a multi-acid that has more than one carboxylate group, including but not limited to, (i) dicarboxylate acids (such as malonic acid, malic acid, et al); dicarboxylic acids with aromatic moieties (such as phthalic acid et al), and combinations thereof; and (ii) tricarboxylic acids (such as citric acid et al), tricarboxylic acids with aromatic moieties (such as trimellitic acid, et al), and combinations thereof.

Preferred acids for the buffer system are polyprotic that have at least three carboxylic acid groups. Such acids have at least a second and a third dissociation constant, each of which is higher relative to its respective preceding constant. This indicates that the acid loses a first proton more easily than a second one, because the first proton separates from an ion of a single negative charge, whereas the second proton separates from the ion of a double negative charge. It is believed that the double negative charge strongly attracts the proton back to the acid ion. A similar relationship exists between the second and third separated protons. Thus, polyprotic acids such as, for example, those having at least three carboxylic acid groups are useful in controlling the pH of a solution, particularly at a pH corresponding to their higher pKa value. Therefore, in addition to having a pKa value of about 5 to about 7, preferred polyprotic acids of the present invention have multiple pKa values, wherein the highest pKa is from about 5 to about 7, or from about 5 to about 6, or from about 6 to about 7, or from about 5.5 to about 6.5.

Polyprotic acids having at least three carboxylic acid groups according to the present invention are highly compatible with polyhydric solvents. Examples of preferred polyprotic acids include tricarboxylic acids (e.g., citric acid, 2-methylpropane-1,2,3-triscarboxylic, benzene-1,2,3-tricarboxylic [hemimellitic], propane-1,2,3-tricarboxylic [tricarballylic], 1,cis-2,3-propenetricarboxylic acid [aconitic], and the like), tetracarboxylic acids (e.g., butane-1,2,3,4-tetracarboxylic, cyclopentanetetra-1,2,3,4-carboxylic, benzene-1,2,4,5-tetracarboxylic [pyromellitic], and the like), pentacarboxlyic acids (e.g., benzenepentacarboxylic), and hexacarboxylic acids (e.g., benzenehexacarboxylic [mellitic]), and the like. The respective pKa values of these acids are provided in Table 1. Particularly preferred polyprotic acids include tricarboxylic acids, with citric acid being most preferred.

TABLE 1

| | pKa value at 25° C. | | | | | |
|---|---|---|---|---|---|---|
| Acid | pK1 | pK2 | pK3 | pK4 | pK5 | pK6 |
| Citric acid | 3.13 | 4.76 | 6.40 | | | |
| 2-Methylpropane-1,2,3- | 3.53 | 5.02 | 7.20 | | | |
| triscarboxylic | | | | | | |
| Benzene-1,2,3-tricarboxylic | 2.98 | 4.25 | 5.87 | | | |
| (hemimellitic) | | | | | | |
| Propane-1,2,3-tricarboxylic | 3.67 | 4.84 | 6.20 | | | |
| (tricarballylic) | | | | | | |
| 1,cis-2,3-Propenetricarboxylic | 3.04 | 4.25 | 5.89 | | | |
| acid, (aconitic) | | | | | | |
| Butane-1,2,3,4-tetracarboxylic | 3.36 | 4.38 | 5.45 | 6.63 | | |
| Cyclopentanetetra-1,2,3,4- | 3.07 | 4.48 | 5.57 | 10.06 | | |
| carboxylic | | | | | | |
| Benzene-1,2,4,5-tetracarboxylic | 2.43 | 3.13 | 4.44 | 5.61 | | |
| (pyromellitic) | | | | | | |
| Benzenepentacarboxylic | 2.34 | 2.95 | 3.94 | 5.07 | 6.25 | |
| Benzenehexacarboxylic | 2.08 | 2.46 | 3.24 | 4.44 | 5.50 | 6.59 |
| (mellitic) | | | | | | |

Citric acid, the preferred polyprotic acid, is a tricarboxylic acid having three pKa values: 3.13, 4.76, and 6.40, corresponding to trihydrogencitrate ions, dihydrogencitrate ions, and monohydrogen citrate ions, respectively. In certain preferred embodiments of the present invention, the buffer system comprises a salt of citric acid, with especially preferred buffers comprising aqueous solutions of ammonium citrate tribasic and citric acid.

The polyfunctional acid component of the buffer, in combination with the ammonium salts containing component of the buffer, exerts a buffering action on the composition of the present invention. When the above-mentioned acids are reacted with the ammonium base according to the embodiment, they form, for example, ammonium chloride, ammonium sulfate, ammonium nitrate, ammonium carbonate, ammonium hypochlorite, ammonium chlorate, ammonium permanganate, ammonium acetate, dibasic ammonium phosphate, diammonium citrate, triammonium citrate (TAC), ammonium sulfamate, ammonium oxalate, ammonium formate, ammonium tartrate, ammonium bitartrate and ammonium glycolate. In some embodiments, one or more of the above-listed ammonium salts may be added to the composition as part of the buffer (in addition to the polyfunctional acid) to buffer the composition. In those embodiments the buffer may comprise the one or more than one ammonium salt and the one or more than one polyfunctional acid.

It is believed that the amount of polyfunctional organic acid in the compositions of the present disclosure will be from about 0.1 wt % to about 5 wt %, or from about 0.25 wt % to about 3 wt %, or from about 0.3 wt % to about 2.5 wt %, or from about 0.5 wt % to about 2 wt %, or from about 0.3 to about 2 wt %, or from about 0.3 to about 1.5 wt %, or from about 0.1 wt % to about 1 wt %. The weight percent of the polyfunctional organic acid in the composition may be present in a range with start and end points selected from the following group of numbers: 0.01, 0.02, 0.03, 0.04, 0.05, 0.7, 0.09. 0.1, 0.2, 0.3, 0.5, 0.7, 0.9, 1, 1.5, 2, 2.5, 3, 5, 7, 10, 15 and 20. The amount of the base, amine, and/or ammonium salt that acts as the buffer with the polyfunctional organic acid may be present in the composition in an amount that from 1:10 to 10:1, or from 1:8 to 8:1, or from 1:5 to 5:1, or from 1:3 to 3:1, or from 1:2 to 2:1, or from 1.5:1 to 1:1.5, or from 1.3:1 to 1:1.3 or from 1.1:1 to 1:1.1 the weight of the polyfunctional organic acid.

Preferably, the buffer composition of the disclosed etching compositions buffer the compositions so they are alkaline. In some embodiments, the pH is from 2 to 12. In other embodiments, the pH is from 2 to 10. In other embodiments, the pH is from 3 to 9. In other embodiments the pH may be within a range with start and end points selected from the following group of pH values: 2, 3, 3.5, 4, 4.5, 5, 5.5, 6, 6.5, 7, 7.5, 8, 8.5, 9, 9.5, 10, 10.5, 11, 11.5, 12, 13. 13.5.

### Other Optional Ingredients

The etching composition of the present invention may also include one or more of the following additives: chelating agents, chemical modifiers, dyes, biocides, and other additives. The additive(s) may be added to the extent that they do not adversely affect the performance of the composition.

Another optional ingredient that can be used in the etching composition is a metal chelating agent; it can function to increase the capacity of the composition to retain metals in solution and to enhance the dissolution of metallic residues. Typical examples of chelating agents useful for this purpose are the following organic acids and their isomers and salts: ethylenediaminetetraacetic acid (EDTA), butylenediaminetetraacetic acid, (1,2-cyclohexylenediamine)tetraacetic acid (CyDTA), diethylenetriaminepentaacetic acid (DETPA), ethylenediaminetetrapropionic acid, (hydroxyethyl)ethylenediaminetriacetic acid (HEDTA), N, N,N′, N′-ethylenediaminetetra(methylenephosphonic) acid (EDTMP), triethylenetetraminehexaacetic acid (TTHA), 1,3-diamino-2-hydroxypropane-N,N,N′,N′-tetraacetic acid (DHPTA), methyliminodiacetic acid, propylenediaminetetraacetic acid, nitrotriacetic acid (NTA), tartaric acid, gluconic acid, saccharic acid, glyceric acid, oxalic acid, phthalic acid, maleic acid, mandelic acid, malonic acid, lactic acid, salicylic acid, propyl gallate, pyrogallol, 8-hydroxyquinoline, and cysteine. Preferred chelating agents are aminocarboxylic acids such as EDTA, CyDTA and aminophosphonic acids such as EDTMP.

It is believed that the chelating agent, if present, will be in the composition in an amount of from about 0.1 wt. % to about 10 wt. %, preferably in an amount of from about 0.5 wt. % to about 5 wt. % of the composition.

In some embodiments the compositions of this invention will be free of or substantially free of any or all or some (in any combination) of the above-listed chelating agents added to the composition.

Other commonly known components such as dyes, biocides etc. can be included in the cleaning composition in conventional amounts, for example, amounts up to a total of about 5 weight % of the composition. In other embodiments the composition will be substantially free of or free of dyes and biocides.

In other embodiments, the etching solution will be substantially free of (or free of) sodium and/or calcium. In some embodiments, the compositions disclosed herein are formulated to be substantially free of at least one of the following chemical compounds: inorganic acids, alkyl thiols, and organic silanes. In some embodiments, the compositions disclosed herein are formulated to be substantially free or free of inorganic bases. In some embodiments, the composition is free of chelating agents, such as EDTA and/or corrosion inhibitors, such as triazoles. In some embodiments, the composition may be substantially free of or free of one or more of the following: hydroxides, metal hydroxides, such as KOH or LiOH or NaOH. In other embodiments, the composition may be substantially free of or free of a halide-containing compound other than one or more fluorine-containing compounds, for example it may be substantially free or free of one or more of the following: bromine-, chlorine- or iodine-containing compounds. In other embodiments, the composition may be substantially free or free of sulfonic acid and/or phosphoric acid and/or sulfuric acid and/or nitric acid and/or hydrochloric acid. In other embodiments, the composition may be substantially free or free of sulfates and/or nitrates and/or sulfites and/or nitrites. In other embodiments, the composition may be substantially free or free of: ammonium hydroxide and/or ethyl diamine. In other embodiments, the composition may be substantially free or free of: sodium-containing compounds and/or calcium-containing compounds and/or manganese-containing compounds or magnesium-containing compounds and/or chromium-containing compounds and/or sulfur-containing compounds and/or silane-containing compounds and/or phosphorus-containing compounds. Some embodiments may be substantially free of or free of non-ionic and/or anionic, and/or cationic surfactants, and/or polyethyleneimines.

The etching solution composition of the present invention is typically prepared by mixing the components together in a vessel at room temperature until all solids have dissolved in the aqueous-based medium.

### Method

In another aspect there is provided a method for simultaneously etching silicon and silicon-germanium in a composite semiconductor device comprising silicon and silicon-germanium by contacting the composite semiconductor device with a composition comprising, consisting essentially of, or consisting of water; an oxidizer; a buffer composition comprising an amine compound and a polyfunctional organic acid; a water-miscible solvent; and a fluoride ion source. The method comprises the steps of simultaneously etching silicon and silicon-germanium on a composite semiconductor device comprising silicon and silicon-germanium, the method comprising the steps of: contacting the composite semiconductor device comprising silicon and silicon-germanium with an aqueous composition comprising water; an oxidizer; a buffer composition comprising an amine compound and a polyfunctional organic acid; a water-miscible solvent; and a fluoride ion source; and rinsing the composite semiconductor device after the silicon and silicon-germanium is at least partially removed, wherein the etch rate for silicon relative to silicon-germanium is within the range of about 2:1 to 1:2. An additional drying step may also be included in the method. “At least partially removed” means removal of at least 50% of the material, preferably at least 70% removal. Most preferably, at least 80% removal using the compositions of the present invention.

The silicon may be in any orientation such as, for example (100) or (110). In some embodiments, the orientation of the silicon is (110) and in other embodiments the orientation of the silicon is (100).

The contacting step can be carried out by any suitable means such as, for example, immersion, spray, or via a single wafer process. The temperature of the composition during the contacting step is preferably from about 25 to 200° C. and more preferably from about 25 to 100° C. and, more preferably, from about 25 to 100° C.

Compositions of the present invention surprisingly exhibit excellent simultaneous etch for silicon and silicon-germanium when used on substrates that include silicon and silicon-germanium such as, for example, during the manufacture of a stacked gate all around device. In some embodiments, the etch rate of silicon and silicon-germanium can be from 3:1 to 1:3. In some embodiments, the etch rate of silicon and silicon-germanium can be from 1:2.5 to 2.5:1, or 1:2 to 2:1, or 1.9:1 to 1:1.9, or 1.8:1 to 1:1.8, or 1.7:1 to 1:1.7, or 1.6:1 to 1:1.6, or 1.5:1 to 1:1.5, or 1.4:1 to 1:1.4, or 1.3:1 to 1:1.3, or 1.2:1 to 1:1.2, or 1.1:1 to 1:1.1. In other embodiments, the etch rate of silicon and silicon-germanium can be about 1:1. The removal rate ratios are measured in the change in thickness (for example of a fin) before and after treatment.

After the contacting step is an optional rinsing step. The rinsing step may be carried out by any suitable means, for example, rinsing the substrate with de-ionized water by immersion or spray techniques. In preferred embodiments, the rinsing step may be carried out employing a mixture of de-ionized water and an organic solvent such as, for example, isopropyl alcohol.

After the contacting step and the optional rinsing step is an optional drying step that is carried out by any suitable means, for example, isopropyl alcohol (IPA) vapor drying, heat, by centripetal force or by directing clean dry air or inert gas and/or combinations thereof.

The features and advantages are more fully shown by the illustrative examples discussed below.

### EXAMPLES

### General Procedure for Preparing the Cleaning Compositions

All compositions which are the subject of the present Examples were prepared by mixing the components in a 250 mL beaker with a 1″ Teflon-coated stir bar. Typically, the first material added to the beaker was deionized (DI) water followed by the other components in no particular order.

### Compositions of the Substrate

Si or SiGe blanket wafers were used to check the etch rate for formulation development. A patterned wafer with Si and SiGe fins was used to confirm the fin trimming using a composition of this invention.

### Processing Conditions

Etching tests of silicon and SiGe were run using 100g of the etching compositions in a 250 ml beaker with a ½″ round Teflon stir bar set at 400 rpm. The etching compositions were heated to a temperature of about 45° C. on a hot plate (typically from 25° C. to 80° C.). The test coupons were immersed in the compositions for about 20 minutes while stirring.

The segments were then rinsed for 3 minutes in a DI water bath or sprayed and subsequently dried using filtered nitrogen. The silicon and silicon-germanium etch rates were estimated from changes in the thickness before and after etching and was measured by Transmission Electron Microscope.

### Examples

Table 1 lists compositions evaluated.

| Raw Material | RM Assay, wt % | Example 1 | Example 2 | Example 3 |
|---|---|---|---|---|
| H2O2 (30%) | 30 | 10.00 | 5.00 | 2.00 |
| TAC | 100 | 0.60 | 0.60 | 0.60 |
| Citric acid | 100 | 0.50 | 0.50 | 0.50 |
| DIW | | 65.80 | 89.80 | 88.80 |
| NH4F (40%) | 40 | 2.50 | 3.50 | 2.50 |
| AEE | | 0.60 | 0.60 | 0.60 |
| BDG | | 20.00 | 0.00 | 5.00 |

| | | | |
|---|---|---|---|
| Total | 100.00 | 100.00 | 100.00 |

Referring to Table 2, the compositions of Table 1 were employed at a process temperature of 25° C. and a process time of 50 seconds and Example 2 was also tested at 90 seconds. The Si trimming thickness was 0.9 nm and the SiGe trimming was 1.2 nm for the Example 1 composition providing a removal rate ratio of Si:SiGe of 1:1.33. Example 2 after 50 seconds provided a Si trimming thickness of 4.5 nm and a SiGe trimming of 1.9 nm providing a removal rate ratio of SiGe:Si of 1:2.36. Example 3 provided a Si:SiGe removal rate of 1:1.11. The trimming thickness of Examples 1 and 3 were both approximately 1 nm. Additionally, the compositions were compatible with oxide and nitride. Example 2 at 90 seconds removed 100% of both the Si and SiGe. The process times can be modified to improve the results.

TABLE 2
Conditions and Results

| | | | | | | Trim- | | |
|---|---|---|---|---|---|---|---|---|
| | | | | Pro- | | ming | Oxide | SiN |
| | | | | cess | | Thick- | E/R | E/R |
| Chem- | Temp. | | Before | time | After | ness | (A/ | (A/ |
| ical | (C.) | Fin | (nm) | (s) | (nm) | (nm) | min) | min) |
| Exam- | 25 | Si | 6.5-8.1 | 50 | 5.9-6.8 | 0.9 | <1 | <1 |
| ple | | SiGe | 4.9-5.7 | 50 | 3.3-4.9 | 1.2 | | |
| 1 | | | | | | | | |
| Exam- | 25 | Si | 6.3-7.9 | 50 | 2.3-2.9 | 4.5 | <1 | <1 |
| ple | | SiGe | 5.2-6.3 | 50 | 3.4-4.2 | 1.9 | | |
| 2 | | | | | | | | |
| Exam- | 25 | Si | 6.3-7.9 | 90 | 0 | >7.1 | <1 | <1 |
| ple | | SiGe | 5.2-6.3 | 90 | 0 | >5.8 | | |
| 2 | | | | | | | | |
| Exam- | 40 | Si | 6.3-7.9 | 50 | 5.4-7.0 | 0.9 | <1 | <1 |
| ple | | SiGe | 5.2-6.3 | 50 | 4.2-5.3 | 1.0 | | |
| 3 | | | | | | | | |

### Comparative Examples

Etching tests were run using 100 g of comparative compositions in a 250 ml beaker with a ½″ round Teflon stir bar set at 400 rpm. The etching compositions were heated to a temperature of about 45° C. on a hot plate. The test coupons were immersed in the compositions for about 20 minutes while stirring.

Wafers having alternating layers of Si and SiGe fins were then rinsed for 3 minutes in a DI water bath or spray and subsequently dried using filtered nitrogen. The silicon and silicon-germanium etch rates were estimated from changes in the thickness before and after etching and was measured by spectroscopic ellipsometry (MG-1000, Nano-View Co., Ltd., South Korea we use SCI FilmTek SE2000). Typical starting layer thickness was 1000 Å for Si and 1000 Å for SiGe.

Table 3 shows the selectivity of poly Si and SiGe for the Comparative Examples The etch rates of poly Si to SiGe were more than 3.4:1.

TABLE 3
Comparative Examples

| | 294F | 294C | 294E | 294G | 294I | 294D | 294H |
|---|---|---|---|---|---|---|---|
| ETMAH (20%) | 15 | 15 | 15 | 15 | 15 | 15 | 15 |
| DIW | 39.7 | 39.7 | 39.7 | 39.7 | 39.7 | 39.7 | 39.7 |
| AEE | 25 | 25 | 25 | 25 | 25 | 25 | 25 |
| Lupasol 800 | 0.3 | | | | | | |
| Glycerol | 20 | | | | | | |
| DMSO | | 20 | | | | | |
| PG | | | 20 | | | | |
| DPM | | | | 20 | | | |
| DIW | | | | | 20 | | |
| sulfolane | | | | | | 20 | |
| BDG | | | | | | | 20 |
| poly Si e/r at 45° C. | 150.3 | 145.2 | 123.2 | 90.5 | 220 | 133 | 84.6 |
| SiGe e/r at 45° C. | 16.6 | 17.4 | 17.8 | 14.4 | 35 | 27.6 | 25.2 |
| Poly Si/SiGe | 9.1 | 8.3 | 6.9 | 6.3 | 6.3 | 4.8 | 3.4 |
| selectivity | | | | | | | |

Lupasol ® 800 which is supplied by BASF is a polyethyleneimine.

The foregoing description is intended primarily for purposes of illustration. Although the invention has been shown and described with respect to an exemplary embodiment thereof, it should be understood by those skilled in the art that the foregoing and various other changes, omissions, and additions in the form and detail thereof may be made therein without departing from the spirit and scope of the invention.

1. An etching solution suitable for the simultaneous removal of silicon and silicon-germanium from a microelectronic device, which comprises:
water;
an oxidizer;
a buffer composition comprising an amine compound and a polyfunctional organic acid;
a water-miscible solvent; and
a fluoride ion source.

2. An etching solution suitable for the simultaneous removal of silicon and silicon-germanium from a microelectronic device, which comprises:
water;
amine;
oxidizer;
buffer composition comprising an ammonium compound and a polyfunctional organic acid;
water-miscible solvent; and
fluoride ion source.

3. The etching solution of claim 1 wherein the oxidizer is elected from the group consisting of hydrogen peroxide, periodic acid, potassium iodate, potassium permanganate, ammonium persulfate, ammonium molybdate, ferric nitrate, nitric acid, potassium nitrate, ammonia, and mixtures thereof.

4. The etching solution of claim 2 wherein the oxidizer is elected from the group consisting of hydrogen peroxide, periodic acid, potassium iodate, potassium permanganate, ammonium persulfate, ammonium molybdate, ferric nitrate, nitric acid, potassium nitrate, ammonia, and mixtures thereof.

5. The etching solution of claim 4 wherein the oxidizer is hydrogen peroxide.

6. The etching solution of claim 1 wherein the amine compound is an alkanolamine compound selected from the group consisting of N-methylethanolamine (NMEA), monoethanolamine (MEA), diethanolamine, triethanolamine, triisopropanolamine, 2-(2-aminoethylamino)ethanol, 2-(2-aminoethoxy)ethanol (AEE), triethanolamine, N-ethyl ethanolamine, N,N-dimethylethanolamine, N,N-diethyl ethanolamine, N-methyl diethanolamine, N-ethyl diethanolamine, cyclohexylaminediethanol, diisopropanolamine, cyclohexylaminediethanol, and mixtures thereof.

7. The etching solution of claim 2 wherein the amine compound is an alkanolamine compound selected from the group consisting of N-methylethanolamine (NMEA), monoethanolamine (MEA), diethanolamine, triethanolamine, triisopropanolamine, 2-(2-aminoethylamino)ethanol, 2-(2-aminoethoxy)ethanol (AEE), triethanolamine, N-ethyl ethanolamine, N,N-dimethylethanolamine, N,N-diethyl ethanolamine, N-methyl diethanolamine, N-ethyl diethanolamine, cyclohexylaminediethanol, diisopropanolamine, cyclohexylaminediethanol, and mixtures thereof.

8. The etching composition of claim 7 wherein alkanolamine is amino(ethoxy) ethanol (AEE).

9. The etching composition of claim 1 wherein the water-miscible solvent is selected from the group consisting of ethylene glycol, propylene glycol, 1,4-butanediol, tripropylene glycol methyl ether, propylene glycol propyl ether, diethylene gycol n-butyl ether, hexyloxypropylamine, poly(oxyethylene)diamine, dimethylsulfoxide, tetrahydrofurfuryl alcohol, glycerol, alcohols, sulfoxides, or mixtures thereof.

10. The etching solution of claim 2 wherein the water-miscible solvent is selected from the group consisting of ethylene glycol, propylene glycol, 1,4-butanediol, tripropylene glycol methyl ether, propylene glycol propyl ether, diethylene gycol n-butyl ether, hexyloxypropylamine, poly(oxyethylene)diamine, dimethylsulfoxide, tetrahydrofurfuryl alcohol, glycerol, alcohols, sulfoxides, or mixtures thereof.

11. The etching solution of claim 2 wherein the water-miscible solvent is butyl diglycerol.

12. The etching solution of claim 1, wherein the amine compound is an alkanolamine and the polyfunctional organic acid is a polyprotic acid having at least three carboxylic acid groups.

13. The etching solution of claim 2, wherein the amine compound is an alkanolamine and the polyfunctional organic acid is a polyprotic acid having at least three carboxylic acid groups.

14. The etching solution of claim 2, wherein the polyfunctional acid is selected from the group consisting of citric acid, 2-methylpropane-1,2,3-triscarboxylic, benzene-1,2,3-tricarboxylic [hemimellitic], propane-1,2,3-tricarboxylic [tricarballylic], 1,cis-2,3-propenetricarboxylic acid [aconitic], e.g., butane-1,2,3,4-tetracarboxylic, cyclopentanetetra-1,2,3,4-carboxylic, benzene-1,2,4,5-tetracarboxylic [pyromellitic], benzenepentacarboxylic, and benzenehexacarboxylic [mellitic]), and mixtures thereof.

15. The etching solution of claim 2 wherein the buffer comprises an ammonium salt selected from the group consisting of ammonium chloride, ammonium sulfate, ammonium nitrate, ammonium carbonate, ammonium hypochlorite, ammonium chlorate, ammonium permanganate, ammonium acetate, dibasic ammonium phosphate, diammonium citrate, triammonium citrate (TAC), ammonium sulfamate, ammonium oxalate, ammonium formate, ammonium tartrate, ammonium bitartrate and ammonium glycolate.

16. The etching solution of claim 15 wherein the buffer comprises triammonium citrate (TAC).

17. A method for simultaneously etching silicon and silicon-germanium from a microelectronic device comprising silicon and silicon-germanium, the method comprising the steps of:
contacting the microelectronic device comprising silicon and silicon-germanium with an etching solution comprising water; an oxidizer; a buffer composition comprising an amine compound and a polyfunctional organic acid; a water-miscible solvent; and a fluoride ion source; and
rinsing the microelectronic device after the silicon and silicon-germanium are at least partially removed, wherein the etch rate for silicon relative to silicon-germanium is from about 3:1 to 1:3.

18. A method for simultaneously etching silicon and silicon-germanium from a microelectronic device comprising silicon and silicon-germanium, the method comprising the steps of:
contacting the microelectronic device comprising silicon and silicon-germanium with an etching solution comprising water; an oxidizer; an amine; a buffer composition comprising an ammonium compound and a polyfunctional organic acid; a water-miscible solvent; and a fluoride ion source; and
rinsing the microelectronic device after the silicon and silicon-germanium are at least partially removed, wherein the etch rate for silicon relative to silicon-germanium is from about 3:1 to 1:3.

19. The method of claim 18 further comprising the step of drying the microelectronic device.

20. The method of claims 18 wherein the etch rate for silicon relative to silicon-germanium is from about 2:1 to about 1:2.

21. The method of any of claims 18 wherein the etch rate for silicon relative to silicon-germanium is substantially 1:1.

22. The method of any of claims 18 wherein the contacting step is performed at a temperature of from about 25° C. to about 80° C.
